(19) United States
(12) Patent Application Publication
(10) Pub. No.: US 2016/0007440 A1
(43) Pub. Date: Jan. 7, 2016

(54) HEAT CHANNELING AND DISPERSING STRUCTURE AND MANUFACTURING METHOD THEREOF

(71) Applicant: SHUNSIN TECHNOLOGY (ZHONG SHAN) LIMITED, Zhongshan (CN)

(72) Inventors: SHUN-LONG LEE, New Taipei (TW); HONG-GUANG HUANG, Shenzhen (CN)

(21) Appl. No.: 14/791,745

(22) Filed: Jul. 6, 2015

(30) Foreign Application Priority Data
Jul. 7, 2014 (CN) 201410319358.0

(51) Int. Cl. H05K 1/02; H05K 1/18; H05K 3/30; H05K 3/12; H05K 3/40

(52) U.S. Cl. CPC H05K 1/0206; H05K 3/1216; H05K 3/4038; H05K 3/303; H05K 1/181; H05K 2201/10106

(57) ABSTRACT

A heat channeling and dispersing structure includes a substrate, a printed circuit board, and a heat-producing electronic element on the printed circuit board. The printed circuit board is mounted on the substrate, which defines a through hole filled with filler. The electronic element covers the hole infilled with filler. The heat generated by the electronic element is conducted through the filler directly to the substrate for heat dissipation.

### FIELD

The subject matter herein generally relates to cooling of electronic devices.

### BACKGROUND

Light-emitting diodes (LED) convert 80 percent of electric energy to thermal energy operating when operating. Typical heat dispersion structures includes a substrate, a printed circuit board, and a coupling layer coupling the printed circuit board to the substrate. The substrate can radiate heat. The LED chip is electronically coupled to the printed circuit board by pads, and transmits heat to the substrate through the pads and the coupling layer.

### BRIEF DESCRIPTION OF THE DRAWINGS

Implementations of the present technology will now be described, by way of example only, with reference to the attached figures, wherein:

FIG. 1 is an isometric view of a heat channeling and dispersing structure in an exemplary embodiment of the present disclosure, the heat channeling and dispersing structure includes a substrate and a printed circuit board coupled to the substrate.

FIG. 2 is a flow chart of an exemplary method for manufacturing the heat channeling and dispersing structure of FIG. 1.

FIG. 3a is a cross-sectional view of forming a substrate, according to the method of FIG. 2.

FIG. 3b is a cross-sectional view of forming a medium layer on the substrate and defining a hole, according to the method of FIG. 2.

FIG. 3c is a cross-sectional view of forming a circuit layer on the medium layer, according to the method of FIG. 2.

FIG. 4 is an isometric view of the hole filled with a filler.

FIG. 5 is an isometric view of a protective layer formed on the printed circuit board.

FIG. 6 is an assembled view of an electronic element coupled to the printed circuit board.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “substantially” is defined to be essentially conforming to the particular dimension, shape or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a heat channeling and dispersing structure and manufacturing method thereof.

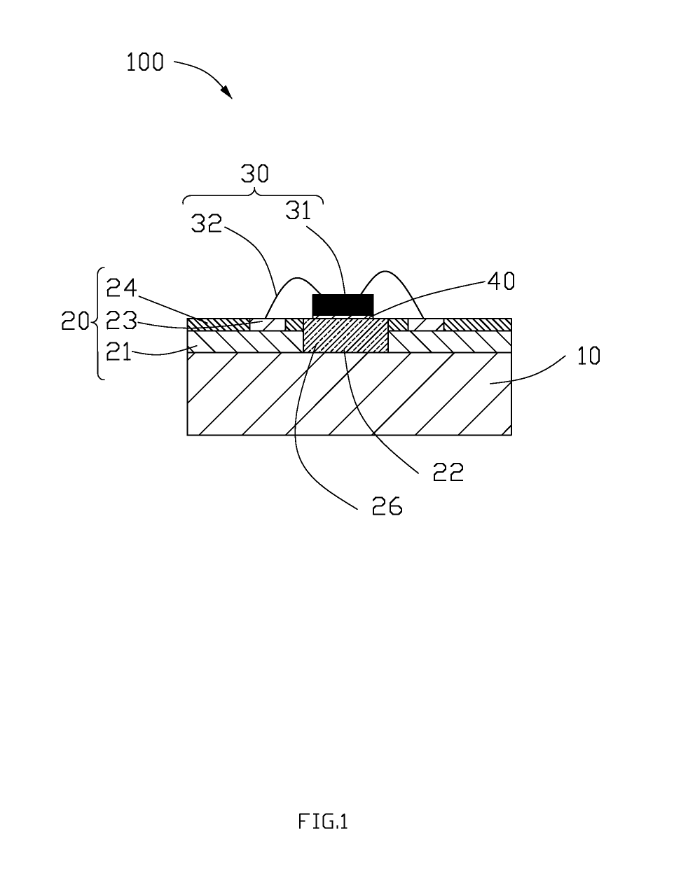

FIG. 1 illustrates an isometric view of a heat dispersion structure 100 according to an exemplary embodiment. The heat dispersion structure 100 includes a substrate 10, a printed circuit board 20, and a filler 26, for use with an electronic element 30. In the illustrated embodiment, the electronic element 30 is a light-emitting diode (LED). The electronic element 30 when operating generates heat. The printed circuit board 20 is mounted on the substrate 10. The printed circuit board 20 defines a hole 22 which is filled with the filler 26. The filler 26 is made of highlighted heat-conductivity material. The heat generated by the electronic element 30 is conducted from the filler 26 to the substrate 10, for heat dissipation.

In detail, the substrate 10 is made of aluminum, in shape of rectangle, and includes a first surface 11 and a second surface 12 opposite to the first surface 11. The printed circuit board 20 is formed on the first surface 11 by silk-screen printing and sintering process. The first surface 11 has a smooth surface. The second surface 12 can be either smooth or finned for increased heat dissipation. In other embodiments, the substrate 10 can be other metal with good radiant properties, such as copper, and the substrate 10 can in other shapes.

The printed circuit board 20 includes a medium layer 21, a printed layer 23, and a protective layer 24. The medium layer 21 is formed on the first surface 11 by silk-screen printing and sintering process and defines the hole 22. The printed layer 23 is formed on the medium layer 21 by silk-screen printing and sintering process. The protective layer 24 is formed on the printed layer 23 by silk-screen printing and sintering process. The hole 22 passes through the medium layer 21, the printed layer 23, and the protective layer 24.

In the illustrated embodiment, the electronic element 30 is located on the printed circuit board 20, away from the first surface 11, and covering the hole 22. The electronic element 30 includes a main body 31, and a wire 32 extending from the main body 31. The main body 31 is electronically coupled to the printed circuit board 20 via an colloid 40, and the wire 32 is electronically coupled to the printed layer 23 to couple the electronic element 30 to the printed circuit board 20. The colloid 40 is located between the main body 31 and the protective layer 24. In other embodiments, a power supply device or other element which requires cooling, such as control circuit, may be mounted on the printed circuit board 20.

In the embodiment, the printed circuit board 20 of the heat dispersion structure 100 defines the hole 22, and the hole 22 is filled with the filler 26 to directly conduct the heat generated by the electronic element 30 to the substrate 10, for heat dissipation.

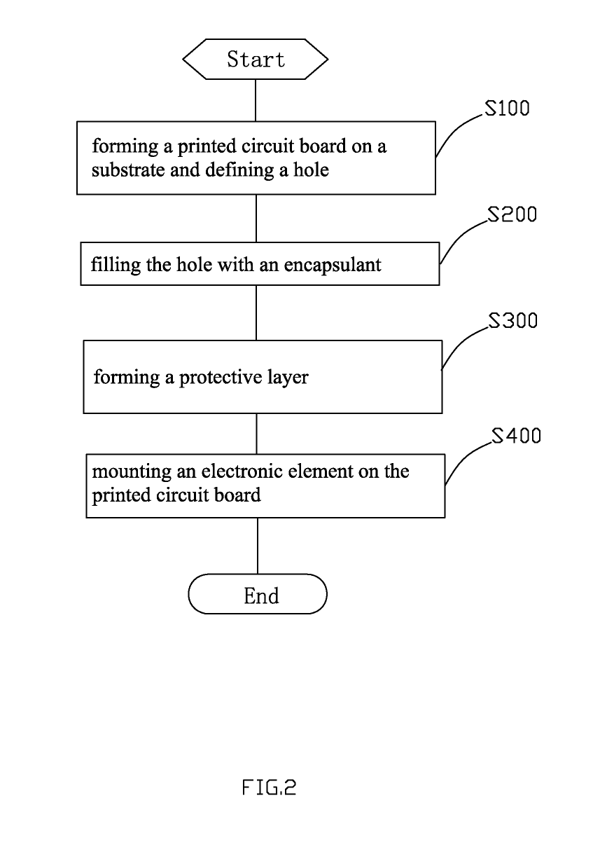

FIG. 2 is a flow chart of a manufacturing method of the heat dispersion structure 100 of an exemplary embodiment of the disclosure. The manufacturing method of the heat channeling and dispersion structure 100 includes blocks as follow.

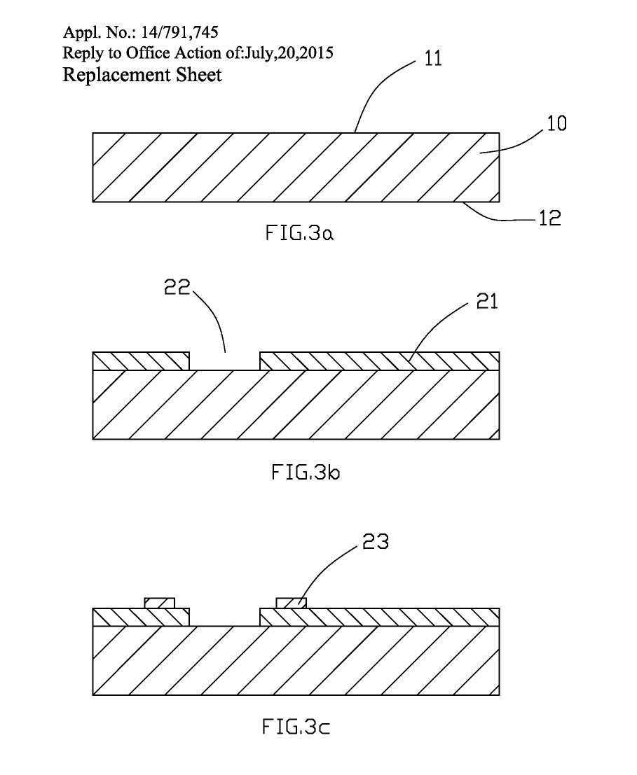

With reference to FIGS. 3a-3c, in block S100, the printed circuit board 20 is formed on the substrate 10. In detail, the substrate 10 includes a first surface 11, and a second surface 12 opposite to the first surface 11. The medium layer 21 is formed on the first surface 11 by silk-screen printing and sintering process and defines the hole 22. The circuit layer 23 is formed on the medium layer 21 by silk-screen printing and sintering process. The medium layer 21 and the circuit layer 23 form a part of the printed circuit board 20.

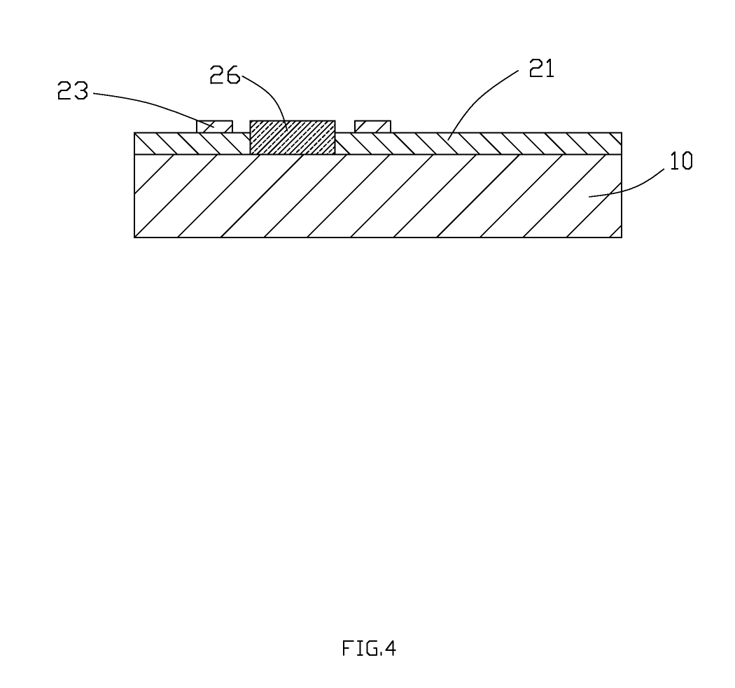

With reference to FIG. 4, in block S200, the hole 22 is filled with the filler 26. The filler 26 is made of highlighted heat-conductive material.

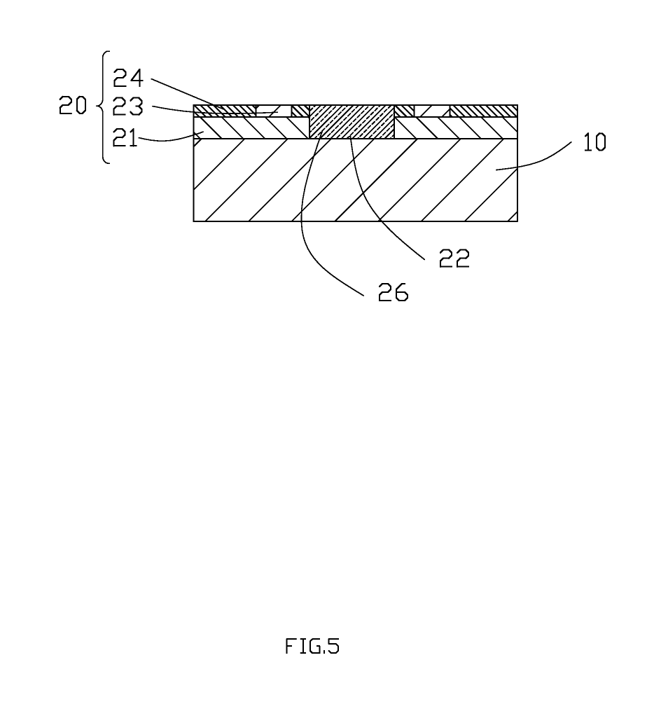

With reference to FIG. 5, in block S300, the protective layer 24 is formed. The protective layer 24 is formed on the circuit layer 23 by silk-screen printing and sintering process or roasting process.

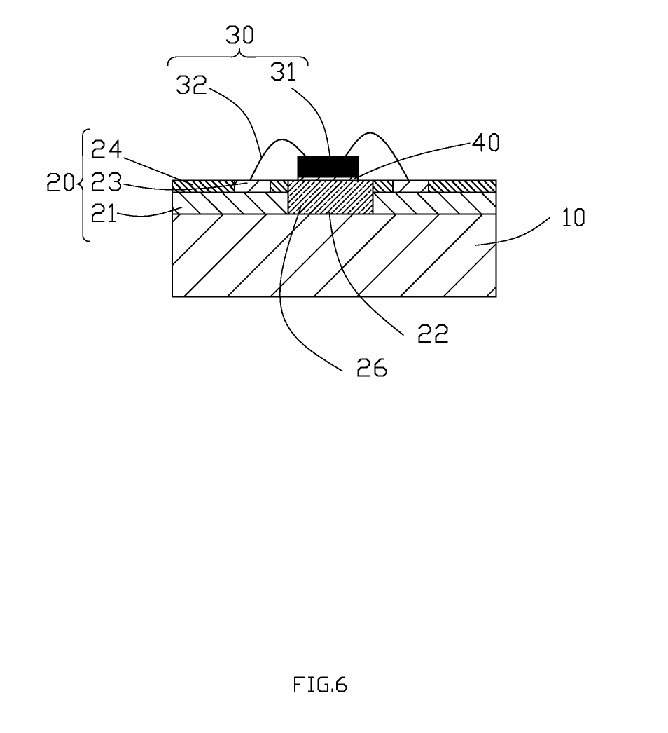

With reference to FIG. 6, in block S400, the electronic element 30 is located on the protective layer 24. In detail, the electronic element 30 is located on a side of the printed circuit board 20 which is away from the first surface 11 and which covers the hole 22. The main body 31 is electronically coupled to the printed circuit board 20 by the colloid 40. The colloid 40 is located between the main body 31 and the protective layer 24. The wire 32 of the electronic element 30 is electronically coupled to the printed layer 23 to couple the element 30 to the printed circuit board 20.

The manufacturing method of the heat dispersion structure 100 of the disclosure improves operating conditions of the element 30 by facilitating heat dissipation. The printed circuit board 20 defines the hole 22, the hole 22 being filled with the filler 26 to conduct heat generated by the electronic element 30 directly to the substrate 10, for heat dissipation.

The embodiments shown and described above are only examples. Many details are often found in the art such as the other features of a heat dispersion structure and manufacturing method thereof. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A heat dispersion structure, comprising:
a substrate;
a printed circuit board mounted on the substrate, defining a hole filled with a filler; and
wherein heat generated by an electronic element positioned on the filler is conducted from the filler to the substrate for heat dissipation.

2. The heat dispersion structure of claim 1, wherein the substrate comprises a first surface, the printed circuit board is located on the first surface by a silk-screen printing and sintering process.

3. The heat dispersion structure of claim 2, wherein the substrate is made of aluminum.

4. The heat dispersion structure of claim 3, wherein the substrate further comprises a second surface opposite to the first surface, the first surface is smooth, and the second surface is either smooth or has fins.

5. The heat dispersion structure of claim 1, wherein the printed circuit board comprises a medium layer formed on the first surface, a circuit layer formed on the medium layer, and a protective layer formed on the circuit layer, and the hole passes through the medium layer, the circuit layer, and the protective layer.

6. The heat dispersion structure of claim 5, wherein the circuit layer is formed on the medium layer by a silk-screen printing and sintering process, and the protective layer is formed on the circuit board by a silk-screen printing and sintering process.

7. The heat dispersion structure of claim 6, wherein the electronic element comprises a main body and a wire extending from the main body, the main body is electronically coupled to the printed circuit board 20 via an colloid, and the wire is electronically coupled to the printed layer to couple the electronic element to the printed circuit board.

8. The heat dispersion structure of claim 1, wherein the filler is made of conductive material.

9. A manufacturing method of the heat dispersion structure, comprising:
printing a printed circuit board on a substrate;
defining a hole on the printed circuit board;
filling the hole with an filler;
locating an electronic element on the printed circuit board and covering the hole to conduct heat generated by the electronic element from the filler to the substrate for heat dissipation.

10. The manufacturing method of the heat dispersion structure of claim 9, wherein the substrate comprises a first surface, the printed circuit board is located on the first surface by a silk-screen printing and sintering process.

11. The manufacturing method of the heat dispersion structure of claim 10, wherein the substrate is made of aluminum.

12. The manufacturing method of the heat dispersion structure of claim 11, wherein the substrate further comprises a second surface opposite to the first surface, the first surface is smooth, and the second surface is either smooth or has fins.

13. The manufacturing method of the heat dispersion structure of claim 9, wherein the printed circuit board comprises a medium layer formed on the first surface, a circuit layer formed on the medium layer, and a protective layer formed on the circuit layer, and the hole passes through the medium layer, the circuit layer, and the protective layer.

14. The manufacturing method of the heat dispersion structure of claim 13, wherein the circuit layer are formed on the medium layer by a silk-screen printing and sintering process, and the protective layer is formed on the circuit board by a silk-screen printing and sintering process.

15. The manufacturing method of the heat dispersion structure of claim 9, wherein the filler is made of conductive material.
